(19) United States
(12) Patent Application Publication
(10) Pub. No.: US 2018/0059289 A1
(43) Pub. Date: Mar. 1, 2018

(54) APPARATUS FOR PLASMA PROCESSING ON OPTICAL SURFACES AND METHODS OF MANUFACTURING AND USE THEREOF

(71) Applicant: Trion Technology, Tempe, AZ (US)

(72) Inventors: Addison Randolph Crockett, Tempe, AZ (US); Mark Andrew Franklin, Tempe, AZ (US)

(21) Appl. No.: 15/693,190

(22) Filed: Aug. 31, 2017

Related U.S. Application Data
(60) Provisional application No. 62/382,518, filed on Sep. 1, 2016.

(51) Int. Cl. G02B 1/12; H01J 37/32; C23C 16/50

(52) U.S. Cl. CPC G02B 1/12; H01J 37/32568; H01J 37/32412; C23C 16/50; G02B 1/11; H01J 37/32596; H01J 37/3244; H01J 2237/3321; H01J 2237/3341

(57) ABSTRACT

Disclosed are apparatus and methods for plasma processing on optical surfaces for anti-reflection (AR) treatments. The present disclosure enables efficient AR treatments and high performance of optical characters of materials having such AR coating. Narrow Gap Plasma Etching and Hollow Cathode Plasma Etching processes are disclosed according to some embodiment of the present invention. In some embodiments, the apparatus and methods are in combination of DC Bias Control to control physical (ion) bombardment and environment of the chamber (pressure and electric power) more closely, thus to control the processing more effectively.

### RELATED APPLICATION

This is a Section 111(a) application relating to and claiming the benefit of co-pending U.S. Provisional Patent Application No. 62/382,518, filed Sep. 1, 2016, the disclosure of which is incorporated by reference in its entirety herein.

### FIELD OF INVENTION

The present disclosure generally relates to apparatus and methods for optics and plasma processing, and particularly relates to apparatus and methods for plasma processing on optical surfaces for anti-reflection treatments.

### BACKGROUND

Anti-reflection (AR) treatments are used widely throughout the optics industry in applications ranging from eyeglasses, lasers, cameras, solar cells, and lithography systems operating on the visible and near infrared light spectrum, to windows, missile domes, security cameras, and laser systems operating on the infrared spectrum.

The conventional thin-film AR coating method is to employ multiple thin layers of dielectric materials deposited onto the external surface of the optical surfaces. However, the resulting AR coating based on the above method does not yield high performance of optical characters. Capabilities of controlling reflections from optical surfaces based on such method are limited.

### SUMMARY

The present disclosure enables efficient AR treatments and high performance of optical characters of materials having such AR coating. Narrow Gap Plasma Etching and Hollow Cathode Plasma Etching processes are disclosed. In some embodiments, the apparatus and methods are in combination of DC Bias Control to control physical (ion) bombardment and environment of the chamber (pressure and electric power) more closely, thus to control the processing more effectively.

As discussed herein, in accordance with one or more embodiments, an apparatus for Narrow Gap Plasma Processing includes a chamber configured to allow one or more gases flowing in the chamber. In one example, a first electrode and a second electrode facing each other are positioned at a distance less than the dark space in the chamber. In some embodiments, the first electrode is configured to be non-powered and the second electrode is configured to be powered. An optic piece to be treated is placed in the first electrode with a tip extended beyond a surface of the first electrode for a length. The apparatus further includes a power supply applying an electric potential across the first electrode and the second electrode.

In accordance with one or more embodiments, a method for Narrow Gap Plasma Processing is disclosed which includes positioning a first electrode and a second electrode facing each other at a distance less than the dark space, wherein the first electrode is configure to be non-powered and the second electrode is configured to be powered; introducing a flow of one or more gases in a space between the first electrode and the second electrode; applying an electrical potential across the first electrode and the second electrode; placing a tip of an optic piece to be treated in the first electrode, wherein the tip is extended beyond a surface of the first electrode; performing plasma processing with ions bombarding a surface of the optic piece to be treated and forming a pattern on the surface of the optic piece to be treated; and continuing the process for sufficient time until a surface texture is fabricated on the optic piece to be treated.

In accordance with one or more embodiments, an apparatus for Hollow Cathode Plasma Processing includes a chamber configured to allow one or more gases flowing in the chamber. A first electrode and a second electrode facing each other are positioned at a distance less than the dark space in the chamber. In some embodiments, the first electrode is configure to be non-powered and the second electrode is configured to be powered. In some embodiments, a hole is configured to be drilled in the first electrode and micro plasmas are configured to be formed near a surface of the first electrode. An optic piece to be treated placed in the first electrode with a tip placed in the hole. The apparatus further includes a power supply applying an electric potential across the first electrode and the second electrode.

In accordance with one or more embodiments, a method for Hollow Cathode Plasma Processing is disclosed which includes positioning a first electrode and a second electrode facing each other at a distance less than the dark space, wherein the first electrode is configure to be non-powered and the second electrode is configured to be powered; drilling a hole in the first electrode; introducing a flow of one or more gases in a space between the first electrode and the second electrode; applying an electrical potential across the first electrode and the second electrode configured to create micro plasmas near a surface of the first electrode; placing a tip of an optic piece to be treated in the hole of the first electrode; performing plasma processing on a surface of the optic piece to be treated with the micro plasmas and forming a pattern on the surface of the optic piece to be treated; and continuing the process for sufficient time until a surface texture is fabricated on the optic piece to be treated.

### BRIEF DESCRIPTION OF THE DRAWINGS

The foregoing and other objects, features, and advantages of the disclosure will be apparent from the following description of embodiments as illustrated in the accompanying drawings, in which reference characters refer to the same parts throughout the various views. The drawings are not necessarily to scale, emphasis instead being placed upon illustrating principles of the disclosure:

FIG. 1 is a schematic diagram illustrating an example of a cross sectional view of an apparatus having a plasma mode reactor used in plasma processing to etch the surface textures into the substrate layers according to some embodiments of the present invention;

FIG. 2 is a schematic diagram illustrating an example of a cross sectional view of an apparatus used in the Narrow Gap Plasma Processing to etch the surface textures of an optic piece to be treated extended between the two electrodes according to some embodiments of the present invention;

FIG. 3 is a flowchart illustrating steps performed according to some embodiments of the present invention;

FIG. 4 is a schematic diagram illustrating an example of a cross sectional view of an apparatus used in the Hollow Cathode Plasma Processing according to some embodiments of the present invention;

FIG. 5 is a flowchart illustrating steps performed according to some embodiments of the present invention;

FIG. 6 is a schematic diagram illustrating an example of a system for applying ICP with bias control during the plasma processing according to some embodiments of the present invention; and

FIG. 7 is a schematic diagram illustrating an example of a system for applying microwave with bias control during the plasma processing according to some embodiments of the present invention.

### DETAILED DESCRIPTION OF EXEMPLARY EMBODIMENTS

One skilled in the art will readily recognize from the following description that alternative embodiments of the structures and methods illustrated herein may be employed without departing from the principles of the invention described herein.

All terms defined herein should be afforded their broadest possible interpretation, including any implied meanings as dictated by a reading of the specification as well as any words that a person having skill in the art and/or a dictionary, treatise, or similar authority would assign thereto.

Throughout the specification and claims, the following terms take the meanings explicitly associated herein, unless the context clearly dictates otherwise. The phrases “in one embodiment” and “in some embodiments” as used herein do not necessarily refer to the same embodiment(s), though it may. Furthermore, the phrases “in another embodiment” and “in some other embodiments” as used herein do not necessarily refer to a different embodiment, although it may. Thus, as described below, various embodiments of the invention may be readily combined, without departing from the scope or spirit of the invention.

The term “based on” is not exclusive and allows for being based on additional factors not described, unless the context clearly dictates otherwise. In addition, throughout the specification, the meaning of “a,” “an,” and “the” include plural references. The meaning of “in” includes “in” and “on.” In addition, the terms “comprises” and “comprising” when used herein specify that certain features are present in that embodiment, however, this phrase should not be interpreted to preclude the presence or additional of additional steps, operations, features, components, and/or groups thereof. The terms, “for example”, “e.g.”, “optionally”, as used herein, are intended to be used to introduce non-limiting examples.

As used herein, the term “at least one of A, B, or C” and the like, means “only A”, “only B”, “only C”, or “any combination of A, B, and C.”

In some embodiments, the present invention is directed to suitable types of AR coating and/or methods of use thereof that include, but not limited to, index-matching, single layer interference, multi-layer interference, absorbing, moth eye, and circular polarizer. In some embodiments, to control reflections from optical surfaces, besides the conventional thin-film AR coating method, plasma processing method is a method to achieve high performance of optical characters. In order to achieve surface relief microstructures, optical phenomena such as diffraction and scattering must be avoided. Thus in some embodiments, the surface structures are required to be fabricated with a periodic spacing smaller than the shortest wavelength employed by the application. In addition, in some embodiments, the height and profile of the surface structures should be sufficient to ensure a slowly varying density change. During the etching, substrates are immersed in a reactive gas (plasma) according to some embodiments. The material to be etched is removed by one or more suitable chemical reactions and/or one or more suitable physical mechanisms. A non-limiting example of a suitable physical mechanism is ion bombardment. The resulting reaction products are volatile and would be carried away in the gas stream.

In some embodiments, the present invention provides an exemplary inventive apparatus and methods of use thereof for achieving a sufficiently high etching rate. In some embodiment, the sufficiently high etching rate is about 0.3 micro/minute or greater. In some embodiments, the present invention provides the exemplary inventive apparatus and methods of use thereof for achieving the sufficiently high efficiency of AR treatments by applying Narrow Gap Plasma Etching and/or Hollow Cathode Plasma Etching according to some embodiment of the present invention. In some embodiments, the apparatus and methods of use thereof are in combination of DC Bias Control to control physical (ion) bombardment and environment of the chamber (pressure and electric power) more closely, thus to control the processing more effectively.

### Illustrative Plasma Processing Examples in Accordance With at Least Some Principles of the Present Invention

In some embodiments, the exemplary plasma processing methodology consists of two primary “processes”: Plasma Etching and Plasma Deposition (PECVD, Plasma Enhanced Chemical Vapor Deposition). “Etching” methods include but not limited to Plasma Etching method (either electrode powered), narrow gap method, hollow cathode method, Ion beam method. In some embodiments, PECVD is a chemical vapor deposition process used to deposit one or more thin films from a gas state (vapor) to a solid state on a substrate. In some embodiments, one or more desired chemical reactions would occur after creation of a plasma of the reacting gases. In one embodiment, the plasma is created by radio frequency (RF) (alternating current (AC)) frequency between two electrodes, the space between which is filled with the reacting gases. In another embodiment, the plasma is created by direct current (DC) discharge between two electrodes.

In some embodiments, the exemplary apparatus and methods of use thereof may be configured to provide surface textures of optical materials, using plasma processing without producing an observable spread of color at ultraviolet wavelengths due to diffraction, and without the size limitations and costs associated with optical lithography or thin-film deposition systems.

In some embodiments, the exemplary inventive plasma processing of the present invention may be used to deposit onto the optical surface at least one suitable composition via polymerization. In some embodiments, the exemplary inventive plasma processing may be used to deposit the at least one suitable composition onto the optical surface via creating micro particles formed of reacted electrode materials. In some embodiments, using the exemplary inventive plasma processing to deposit onto and etch into the optic material(s), a surface texture may be created that does not reflect back the incident light more than about 7% of the incident light). In some embodiments, light transmission efficiency of the optics using the plasma processing ranges from about 93% to over 99.9%. This is may be used for high intensity lasers.

In some embodiments, the exemplary inventive plasma processing may be typically performed in sub-atmospheric gas plasma(s), wherein a solid material may be placed in a reactive gas environment, which would be then produced by electromagnetically energizing gas(s) (thus, creating a gas plasma). During the process of “polymerization,” in some embodiment, the highly reactive gas molecules may react with the solid surfaces and create solid micro-particles. Then during the process of “etching,” in some embodiment, the created micro-particles and/or by-products are pumped away.

In some embodiments, an exemplary inventive plasma etching processing may follow the following steps:
1) surface adsorption including but not limited to:
   i) formation of the reactive particle;
   ii) arrival of the reactive particle at the surface to be etched; and
   iii) chemisorption of the reactive particle at the surface, (chemical bond is formed); and
2) etching including but not limited to:
   iv) formation of the product molecule;
   v) desorption of the product molecule; and
   vi) removal of the product molecule from the reactor (via the gas stream).

In some embodiments, an exemplary inventive plasma deposition processing may follow the following steps:
1) surface adsorption including but not limited to:
   i) formation of the reactive particle; ii) arrival of the reactive particle at the surface; and
   iii) adsorption of the reactive particle at the surface; and
2) micro-mask formation including but not limited to:
   iv) formation of the product micro-particles.

In some embodiments, an exemplary inventive “gas chemistry switching” can be used for more controlled reactive gas processing. The gas chemistry switching uses the above exemplary inventive steps of deposition and processing alternately, i.e., by performing deposition-etching-deposition to better control surface structure of substrate materials. By applying the exemplary inventive “gas chemistry switching,” surface structure can be effectively controlled according to the wavelength of the light beam. For example, for ultraviolet wavelength light beams, the surface structures of the substrate materials can be sufficiently controlled to be finer than those of infrared wavelength light beams. In some embodiments, for the same wavelength light beams, different patterns of surface structures can be achieved by applying the exemplary inventive “gas chemistry switching.” In some embodiments, glass and/or plastic are used for substrate materials. The composition and density of the material varies randomly on a microscopic level, particularly at the surface. In some embodiments, the gas plasma will selectively etch the surface in a manner that matches this random distribution. In addition, exposing the material to the gas plasma allows the formation of carbon, fluorine, oxygen and/or other micro-particles that can form at random locations on the surface of the material and at random times. In some embodiments, these micro-particles can persist for a random amount of time masking the removal of material at that location. In one embodiment, the balance between this micro-masking and material removal is used to vary the nature of the resulting surface texture.

In some embodiments, the reactive gas composition for processing random textures in glass or plastic is a fluorocarbon molecule (such as CF4, CHF3, C4F8, etc.) alone or in combination with oxygen and/or argon. In some embodiments, the fluorocarbon molecules can either form the above micro-particles or create reactive free radicals and/or ions which may etch the surface. This yields sufficiently high density of features with the least amount of undercutting to allow for pattern replication. In one embodiment, the density of ions may be between about 1×10⁻⁶ to 1×10⁻⁸ m⁻³.

In some embodiments, parameters, such as gas composition and gas mixing ratio, were varied to alter the character of the etched surface to match the application requirements.

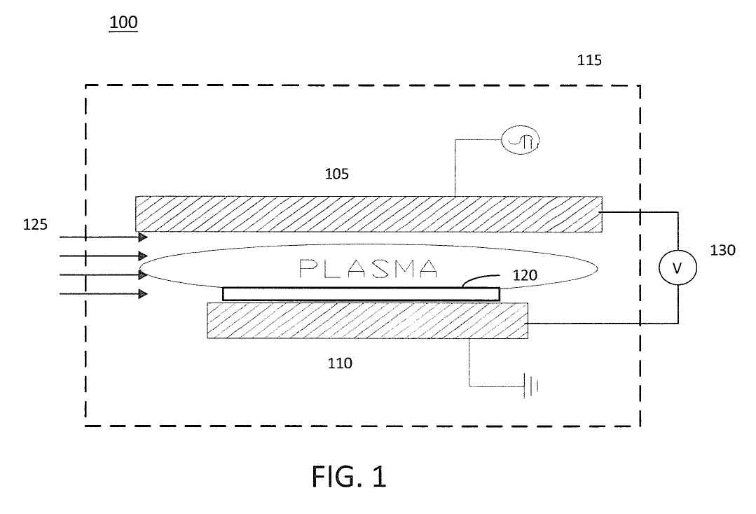

In some embodiments, plasma mode (PE mode or Diode mode) reactors are parallel plate reactors powered on either electrode with isolated plates. FIG. 1 shows a cross sectional view of an apparatus having a plasma mode reactor used in the exemplary inventive plasma processing to etch the surface textures into the substrate layers according to some embodiments. In one embodiment, the exemplary inventive plasma processing system 100 comprises plate electrode 105 and plate electrode 110 positioned at a distance between about 4 cm to 5 cm facing against each other. In one embodiment, the exemplary inventive plasma processing system 100 comprises plate electrode 105 and plate electrode 110 positioned at a distance between about 4 cm to 7 cm facing against each other. In one embodiment, the plate electrode 105 and plate electrode 110 positioned at a distance between about 4 cm to 9 cm facing against each other.

In one embodiment, the powered plate electrode 105 is of equal size of the non-powered (grounded) electrode 110. In one embodiment, the powered plate electrode 105 has a different size from the non-powered (grounded) electrode 110. Both electrodes are contained within a vacuum chamber 115 using a pump system. In one embodiment, the plate electrode 105 is configured to be powered and the plate electrode 110 is configured to be non-powered (grounded). In one embodiment, the plate electrode 110 is configured to be powered and the plate electrode 105 is configured to be non-powered (grounded).

In some embodiments, during the exemplary inventive plasma processing, the substrate to be etched 120 is introduced between the electrodes 105 and 110 and placed upon the non-powered electrode 110 where the exemplary inventive processing takes place. Processing the substrate on the non-powered electrode can prevent the metal sheaths of the electrode to radiate. A flow of a gas 125 capable of chemically processing the substrate material and/or the electrode material is then introduced into the chamber. In one embodiment, the gas can be one type of gas. In one embodiment, the gas can be a mixture of two or more types of gas. An electric potential 130 is applied across the plate electrodes 105 and 110. In one embodiment, the electric potential 130 ranges from about 50 to 600 VDC bias, creating a positive cathode at the substrate 105 and a negative anode at the substrate 110 respectively. The gas 125 is ionized by the electric potential 130 and plasma(s) are formed where the ionized particles in the gas plasma are accelerated toward the substrate 120 where the chemical reaction takes place.

Plasma intensity and operating pressure are both higher compared to those of the Reactive-ion etching (RIE) process, which is a dry etching technology used in microfabrication. In one embodiment, the operating pressure of the plasma process is between about 1 to 2 torr. In one embodiment, the ion density is between about 1×10⁻⁶ to 1×10⁻⁸ m⁻³, which is about 20 times of that of the RIE process. Therefore, it is more efficient for the creation of ions for etching. Two exemplary embodiments of the plasma processing are explained below in further detail.

### Illustrative Narrow Gap Plasma Etching Processing Examples in Accordance With at Least Some Principles of the Present Invention

In some embodiments, during an exemplary inventive Narrow Gap Plasma processing, two electrodes are positioned at a distance less than about 1 cm, which is the dark space distance. The two electrodes “squeeze” the dark space (a “smaller dark space”) sufficiently to create a cascade of electron emission similar to an arc. In one embodiment, the plasma thus operating at an operating pressure between about 1 to 2 torr, which is higher than the regular plasma processing operating pressure. The “smaller dark space” further increases processing efficiency about four times of that of the RIE process.

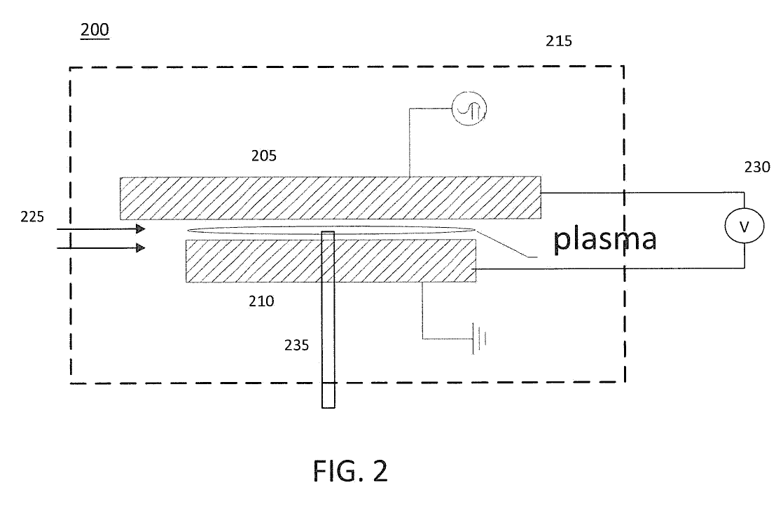

FIG. 2 shows a cross sectional view of an exemplary inventive apparatus used in the exemplary inventive Narrow Gap Plasma processing to etch the surface textures of an optic piece to be treated extended between the two electrodes according to some embodiments. The an exemplary inventive Narrow Gap plasma processing system 200 comprises plate electrode 205 and plate electrode 210. In one embodiment, the two electrodes are positioned at a distance of about 0.5 to 2 cm. In one embodiment, the two electrodes are positioned at a distance of about 1 to 2 cm.

In one embodiment, the plate electrode 205 is configured to be powered and the plate electrode 210 is configured to be non-powered (grounded). A flow of a reactive gas 225 capable of chemically processing the substrate material is then introduced into the chamber 215. An electric potential 230 is applied across the plate electrodes 205 and 210. In some embodiments, a tip of the optic piece to be treated 235 is configured to extend beyond a surface of the non-powered electrode 210 between about 0.5 to 2 mm. In some embodiments, the tip of the optic piece to be treated 235 is configured to extend beyond the surface of the non-powered electrode 210 between about 0 to 1 mm. When sufficiently high pressure plasma(s) are created between the two electrodes, surface pattern is thus formed on the tip of the optic piece to be treated exposed to the sufficiently high pressure plasma. In one embodiment, the sufficiently high pressure plasma has a pressure between about 1 to 2 torr.

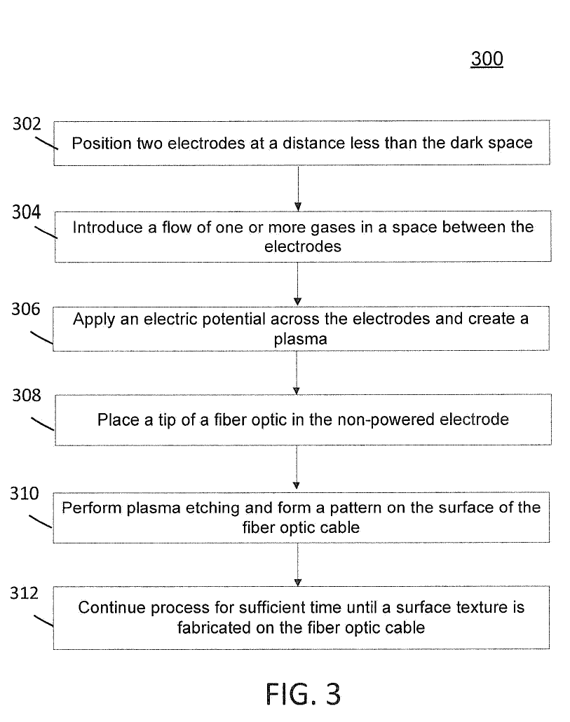

One of the steps in the exemplary inventive narrow gap plasma processing are illustrated in the process of FIG. 3 in accordance with some embodiments of the present disclosure. During the exemplary inventive process, in some embodiments, at step 302, two electrodes are positioned in a chamber opposing to each other and are positioned at a distance less than the normal dark space. One of the two electrodes is powered and the other is grounded (non-powered). At step 304, a flow of one or more gases capable of chemically processing the substrate material is introduced in a space between the two electrodes in the chamber. Then, at step 306, an electric potential is applied across the two electrodes, creating a positive cathode and a negative anode at the two electrodes respectively. The sufficiently high pressure plasma(s) in between the two electrodes are thus created. In one embodiment, the high pressure plasmas have a pressure between about 1 to 2 torr.

After the electric potential is applied, at step 308, a tip of an optic is placed in the non-powered electrode and the tip of the optic piece to be treated is extended beyond a distance above the surface of the non-powered electrode. At step 310, the created plasma(s) are configured to perform plasma processing on the substrate surface and a pattern is formed on the surface of the optic piece to be treated. The exemplary inventive process is continued for a sufficient time period of about 2 to 15 minutes as required at step 312 until a surface texture is fabricated on the optic piece to be treated.

### Illustrative Hollow Cathode Plasma Etching Processing Examples in Accordance With at Least Some Principles of the Present Invention

In some embodiments, during an exemplary inventive Hollow Cathode Plasma processing, a cascade effect and intense plasma are created similar to the exemplary inventive Narrow Gap Plasma processing. In some embodiments, the two opposing electrodes are positioned in plasma at a distance that is smaller than the dark space. In addition, in one embodiment, a hole is drilled in one of the electrodes and a hollow cathode effect can be created and micro plasmas are formed on the surface of the electrode having a hole. A tip of the optic piece to be treated is positioned in this “hollow cathode” hole and micro plasmas on the electrode is configured to achieve sufficiently fast processing on the surface of the optic piece to be treated in a small area within the hole. In some embodiment, the processing rate is as fast as about 0.3 micro/minute or greater.

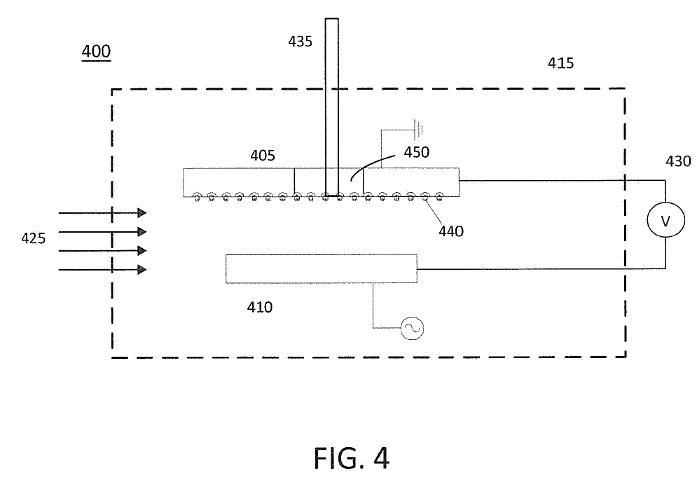

FIG. 4 shows a cross sectional view of an apparatus used in the exemplary inventive Hollow Cathode Plasma processing according to one embodiment. In one embodiment, the exemplary inventive Hollow Cathode Plasma processing system 400 is placed in a chamber 415. In one embodiment, plate electrode 410 is powered and plate electrode 405 is non-powered (grounded), and the two electrodes are positioned at a distance between about 0.1 to 1 cm, which is less than the dark space distance. In one embodiment, the two electrodes are positioned at a distance between about 0.5 to 2 cm. In one embodiment, the two electrodes are positioned at a distance between about 1 to 2 cm.

In one embodiment, a hole 450 is drilled in the non-powered electrode 405. In one embodiment, the hole has a diameter of about 6 mm. In some embodiments, a size of the hole is custom to a size of an optic core size plus about 0.2 mm for fitment. In some embodiments, the size of the hole is custom to the size of an optic core size plus about 0.1 mm for fitment. In some embodiments, the size of the hole is custom to the size of an optic core size plus about 0.3 mm for fitment.

In some embodiments, during the exemplary inventive processing, a flow of a gas 425 capable of chemically processing the substrate material is introduced into the chamber 415. An electric potential 430 is applied across the plate electrodes 405 and 410. A tip of an optic piece to be treated 435 is positioned in the drilled hole 450 on the non-powered electrode 405. Micro plasmas 440 are formed near the surface of the non-powered electrode 405 configured for processing the tip of the optic piece to be treated 435 positioned in the drilled hole 450. In some embodiments, the tip of the optic piece to be treated 435 is configured to extend beyond the surface of the non-powered electrode 405 between about 0 to 2 mm. In some embodiments, the tip of the optic piece to be treated 435 is configured to extend beyond the surface of the non-powered electrode 405 between about 0 to 1 mm.

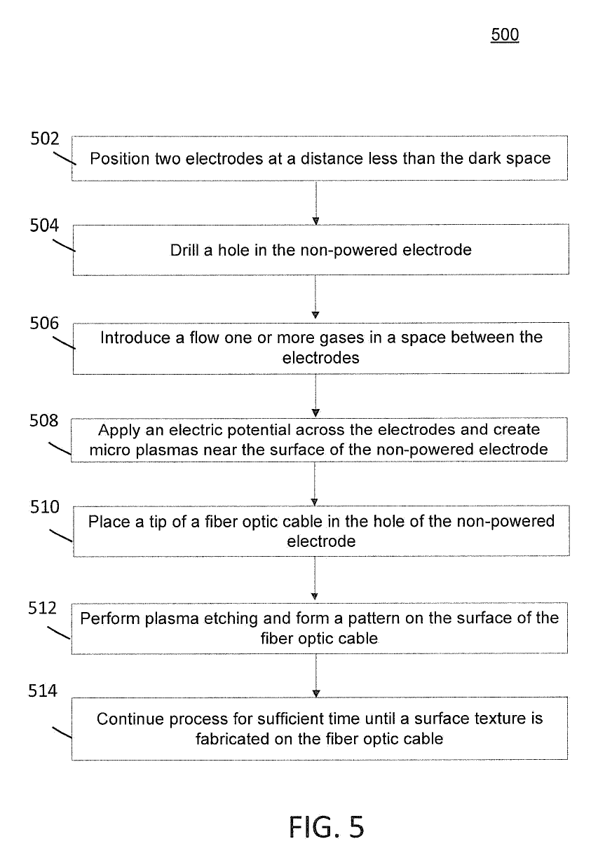

The main steps in the exemplary inventive Hollow Cathode Plasma processing are illustrated in the process of FIG. 5 in accordance with some embodiments of the present disclosure. During the exemplary inventive process, in some embodiments, at step 502, two electrodes are positioned in a chamber opposing to each other and positioned at a distance less than the dark space. One of the two electrodes is powered and the other is grounded (non-powered). At step 504, a hole is drilled on the non-powered electrode. At step 506, a flow of one or more gases capable of chemically processing the substrate material is introduced in a space between the two electrodes in the chamber. Then, at step 508, an electric potential is applied across the two electrodes, creating a positive cathode and a negative anode at the two electrodes respectively. Micro plasmas are thus created near the surface of the non-powered electrode. At step 510, a tip of an optic piece to be treated is place in the hole in the non-powered electrode. At step 512, micro plasmas near the surface of the non-powered electrode perform plasma processing on the surface of the optic piece to be treated and a pattern is formed. The exemplary inventive process is continued for a sufficient time period of about 5 to 15 minutes as required at step 514 until a surface texture is fabricated on the optic piece to be treated.

### Illustrative DC Bias Control Mechanisms Utilized During the Inventive Plasma Processing Examples in Accordance With at Least Some Principles of the Present Invention

In some embodiments, certain methods can be applied to control DC bias, which is configured to control physical (ion) bombardment and/or environment of the chamber (pressure and/or electric power) more closely, thus to control the processing more effectively.

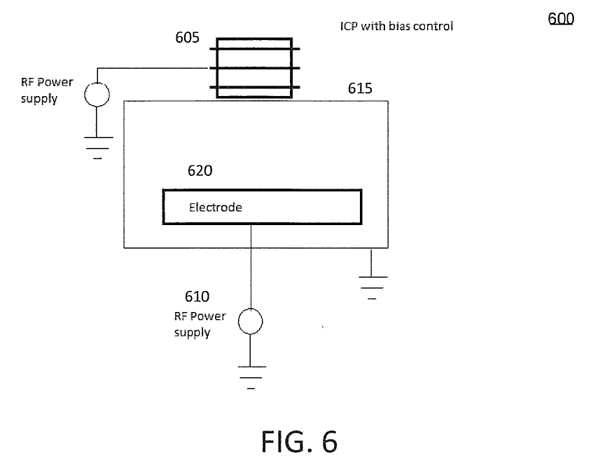

In some embodiments, RF power source can be used for DC bias control. In one embodiment, Inductive Coupled Plasmas (ICP) with bias control is applied to control ion bombardment during the processing. FIG. 6 shows an exemplary inventive system for applying ICP with bias control during the exemplary inventive plasma processing according to one embodiment. The exemplary inventive system includes a first RF power supply as an ICP power 605 that controls the plasma density in the chamber 615. In one embodiment, the ICP power 605 is capacitively coupled with RF current of a second RF power supply 610 through wafer sheath of an electrode 620. The coupling is used to control ion energy, thus controlling ion bombarding on material surface to better control etch characteristics.

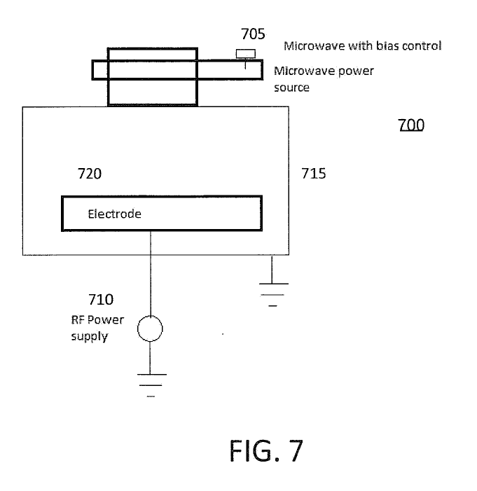

In one embodiment, microwave with bias control may be used for DC bias control during the exemplary inventive processing. FIG. 7 shows an exemplary inventive system for applying microwave with bias control during the exemplary inventive plasma processing according to one embodiment. The exemplary inventive system is placed in a chamber 715. In one embodiment, the exemplary inventive system may include but not limited to a microwave power supply 705 coupled with RF current of an RF power supply 710 through wafer sheath of an electrode 720.

While a number of embodiments of the present invention have been described, it is understood that these embodiments are illustrative only, and not restrictive, and that many modifications may become apparent to those of ordinary skill in the art, including that the inventive methodologies, the inventive systems, and the inventive devices described herein can be utilized in any combination with each other. Further still, the various steps may be carried out in any desired order (and any desired steps may be added and/or any desired steps may be eliminated).

All examples and conditional language recited herein are intended for pedagogical purposes to aid the reader in understanding the principles of the invention and the concepts contributed by the inventor to furthering the art, and are to be construed as being without limitation to such specifically recited examples and conditions. Moreover, all statements herein reciting principles, aspects, and embodiments of the invention, as well as specific examples thereof, are intended to encompass both structural and functional equivalents thereof. Additionally, it is intended that such equivalents include both currently known equivalents as well as equivalents developed in the future, i.e., any elements developed that perform the same.

What is claimed is:

1. An apparatus, comprising:
a chamber configured to allow one or more gases flowing in the chamber;
a first electrode and a second electrode facing each other positioned at a distance less than a dark space distance in the chamber,
wherein the first electrode is configured to be non-powered and the second electrode is configured to be powered;
an optic piece positioned on the first electrode with a tip of the optic piece extending beyond an edge of the first electrode for a predetermined length; and
a power supply configured to apply an electric potential across the first electrode and the second electrode.

2. The apparatus of claim 1, wherein the apparatus is configured to generate a plasma having an ion density of 1×10⁻⁷ m⁻³ or greater.

3. The apparatus of claim 1, wherein the apparatus further comprises:
at least one DC bias control mechanism configured to control at least one condition of at least one of a physical bombardment and an environment of the chamber.

4. The apparatus of claim 1, wherein the first non-powered electrode has a first size and the second powered electrode has a second size, and wherein the first size equals to the second size.

5. The apparatus of claim 1, wherein the first non-powered electrode has a first size and the second powered electrode has a second size, and wherein the first size is smaller than the second size.

6. The apparatus of claim 1, wherein the chamber is a vacuum chamber of a pump system.

7. The apparatus of claim 1, wherein the apparatus is configured to generate a beam having an operating pressure of between 1 to 2 torr and an ion density between 1×10⁻⁶ to 1×10⁻⁸ m⁻³.

8. The apparatus of claim 1, wherein the one or more gases is a reactive gas configured to chemically impact the optic piece.

9. The apparatus of claim 1, wherein a surface pattern is formed on the tip of the optic piece.

10. A method, comprising:
positioning a first electrode and a second electrode facing each other at a distance less than a dark space distance, wherein the first electrode is configure to be non-powered and the second electrode is configured to be powered;
introducing a flow of one or more gases in a space between the first electrode and the second electrode;
applying an electrical potential across the first electrode and the second electrode;
positioning a tip of an optic piece in the first electrode, wherein the tip of the optic piece extending beyond an edge of the first electrode for a predetermined length;
performing plasma processing with ions bombarding a surface of the optic piece to be treated and forming a pattern on the surface of the optic piece to be treated; and
continuing the process for sufficient time until a surface texture is fabricated on the optic piece to be treated.

11. The method of claim 10, wherein the method is configured to generate a plasma having an ion density of about 1×10⁻⁷ m⁻³ or greater.

12. The method of claim 10, wherein the one or more gases is a reactive gas configured to chemically impact the optic piece.

13. The method of claim 10, wherein the sufficient time is about 2 to 15 minutes.

14. An apparatus, comprising:
a chamber configured to allow one or more gases flowing in the chamber;
a first electrode and a second electrode facing each other positioned at a distance less than a dark space distance in the chamber,
wherein the first electrode is configure to be non-powered and the second electrode is configured to be powered,
wherein a hole is configured to be drilled in the first electrode and micro plasmas are configured to be formed near a surface of the first electrode;
an optic piece positioned on the first electrode with a tip of the optic piece positioned in the hole; and
a power supply configured to apply an electric potential across the first electrode and the second electrode.

15. The apparatus of claim 14, wherein the apparatus is configured to generate a plasma having an ion density of about 1×10⁻⁷ m⁻³ or greater.

16. The apparatus of claim 14, wherein the apparatus further comprises:
at least one DC bias control mechanism configured to control at least one condition of at least one of a physical bombardment and an environment of the chamber.

17. The apparatus of claim 14, wherein the hole in the first electrode as a diameter of about 6 mm.

18. The apparatus of claim 14, wherein a size of the hole is custom to a size of an optic core size plus about 0.2 mm for fitment.

19. The apparatus of claim 14, wherein the one or more gases is a reactive gas configured to chemically impact the optic piece.

20. The apparatus of claim 14, wherein the micro plasmas are formed near the surface of the first electrode configured to process the tip of the optic piece to be treated.

21. The apparatus of claim 14, wherein applying the electric potential across the first electrode and the second electrode creates a positive cathode and a negative anode at the two electrodes respectively.

22. A method, comprising:
positioning a first electrode and a second electrode facing each other at a distance less than a dark space distance, wherein the first electrode is configure to be non-powered and the second electrode is configured to be powered;
drilling a hole in the first electrode;
introducing a flow of one or more gases in a space between the first electrode and the second electrode;
applying an electrical potential across the first electrode and the second electrode configured to create micro plasmas near a surface of the first electrode;
positioning a tip of an optic piece in the hole of the first electrode;
performing plasma processing on a surface of the optic piece to be treated with the micro plasmas and forming a pattern on the surface of the optic piece to be treated; and
continuing the process for sufficient time until a surface texture is fabricated on the optic piece to be treated.

23. The method of claim 22, wherein the method is configured to generate a plasma having an ion density of about 1×10⁻⁷ m⁻³ or greater.

24. The method of claim 22, wherein the sufficient time is about 5 to 15 minutes.
